(19) United States
(12) Patent Application Publication
(10) Pub. No.: US 2010/0148801 A1
(43) Pub. Date: Jun. 17, 2010

(54) CAPACITANCE-TYPE ENCODER

(75) Inventors: Hiroyuki UCHIDA, Minamitsuru-gun (JP); Mitsuyuki Taniguchi, Minamitsuru-gun (JP); Shunichi Odaka, Minamitsuru-gun (JP); Isao Kariya, Minamitsuru-gun (JP); Hidetoshi Mitsui, Minamitsuru-gun (JP)

Correspondence Address: DRINKER BIDDLE & REATH (DC), 1500 K STREET, N.W., SUITE 1100, WASHINGTON, DC, 20005-1209, US

(73) Assignee: FANUC LTD, Minamitsuru-gun (JP)

(21) Appl. No.: 12/566,798

(22) Filed: Sep. 25, 2009

(30) Foreign Application Priority Data
Dec. 12, 2008 (JP) 2008-317756

(51) Int. Cl. G01R 27/26

(52) U.S. Cl. 324/660; 324/683

(57) ABSTRACT

A capacitance-type encoder capable of obtaining position data of a movable element with low power-consumption. The capacitance-type encoder comprises a stator, a movable element arranged to confront the stator, an excitation device and a signal processing device. The stator has at least three excitation-electrode sets electrically independent from each other, each set constituted of excitation electrodes arranged cyclically and electrically connected with each other so that a predetermined number of excitation-electrode groups are formed. The movable element has connection electrodes having the same number as the excitation-electrode groups. The excitation device applies excitation signals to the excitation-electrode sets periodically in a predetermined sequence. The signal processing device determines which one of divided regions of one cycle of arrangement of the excitation electrodes the movable element is positioned in based on a combination pattern of detection signals generated in the connection electrodes.

### BACKGROUND OF THE INVENTION

1. Field of the Invention

The present invention relates to an encoder for detecting a relative position of a movable element such as a rotor with respect to a stator fixedly provided, and in particular to a capacitance-type encoder capable of acquiring position information with low power-consumption utilizing capacitive coupling.

2. Description of Related Art

There is known a capacitance-type encoder as a sensor for acquiring rotational information about a body of rotation. The capacitance-type encoder is capable of acquiring rotational information of the body of rotation with high sensitivity using high frequency signals and also with a thin structure utilizing a principle of capacitive coupling so that the encoder can be made small.

A capacitance-type encoder as disclosed in JP61-105421A comprises a rotary plate 10 mounted on a rotary shaft to be rotatable with respect to a body and a stationary plate 12 mounded on the body to confront the rotary plate 10 so as to detect a rotational displacement of the rotary plate with respect to the stationary plate.

A plurality of sending electrodes are arranged at regular intervals in a circumferential direction on a surface of the stationary plate. A voltage application circuit applies sinusoidal waves or rectangular waves with their phases successively displaced by a predetermined degree to the sending electrodes so that a plurality of electrode groups are formed with eight phase electrodes as a unit. For applying sinusoidal waves, it is necessary to provide a complicated analog amplifier capable of generating intermediate voltages, to increase power consumption.

Receiving electrodes having the same number as the electrode groups are arranged on a surface of the rotary plate such that each receiving electrode confronts successive sending electrodes in each electrode group on the stationary plate.

As described, in the capacitance-type encoder, there has been adopted a configuration where a plurality of sending electrodes are arranged at regular intervals and alternating voltages with predetermined displaced phases are applied to respective excitation electrodes, and receiving electrodes are arranged to confront the excitation electrodes to acquire a relative motion amount between the sending electrodes and the receiving electrodes by analyzing phase differences of capacitive signals detected by the receiving electrodes and the applied alternating voltages. It has been required to perform a position detection of a movable element such as a body of rotation with high accuracy using the capacitance-type encoder which has a small size and a light weight and also low power consumption, in view of backup of a power source of the capacitance-type encoder by a battery to maintain a function of the encoder when the power source is shut down.

### SUMMARY OF THE INVENTION

The present invention provides a capacitance-type encoder capable of obtaining position data with low power-consumption based on signals from a movable element.

A capacitance-type encoder of the present invention comprises: a stator having at least three excitation-electrode sets electrically independent from each other, each set constituted of excitation electrodes arranged cyclically and electrically connected with each other so that a predetermined number of excitation-electrode groups are formed, and a receiving electrode electrically independent from the excitation electrodes; a movable element provided movably relative to the stator and having connection electrodes arranged to confront the excitation electrodes of the stator cyclically to have the same number as the excitation-electrode groups, and a sending electrode electrically connected with the connecting electrodes and arranged to confront the receiving electrode of the stator; excitation means for applying excitation signals of binary voltages to the excitation-electrode sets of the stator periodically in a predetermined sequence; and signal processing means for processing detection signals generated in the connection electrodes of the movable element and received by the receiving electrode through the sending electrode when the excitation signals are applied to the excitation electrodes of the stator to determine which one of divided regions the movable element is positioned in based on a combination pattern of the detection signals, the divided regions being predetermined by dividing one cycle of arrangement of excitation electrodes in each excitation-electrode group by the number of the excitation-electrode sets.

The excitation signals may comprise positive or negative pulse voltages.

The movable element may be a rotor to perform a rotary motion or a linear motion element to perform a linear motion with respect to the stator.

In contrast to the prior art capacitance-type encoder in which high frequency alternating-current signals are continuously applied to the sending electrodes, according to the capacitance-type encoder of the present invention position data of a movable element are obtained with low power-consumption by applying single pulse voltages to the excitation electrodes at appropriate frequency.

### BRIEF DESCRIPTION OF THE DRAWINGS

FIG. 1 is a front view of a stator of a capacitance-type encoder according to the present invention;

FIG. 2 is a front view of a movable element of the capacitance-type encoder;

FIG. 3 is a schematic diagram of the capacitance-type encoder;

FIG. 4 is a diagram showing positions of a connection electrode on the movable element with respect to excitation electrodes on the stator, waveforms of excitation signals applied to the excitation electrodes and detection signals according to a first embodiment of the present invention;

FIG. 5a is a table showing relation between combinations of detection signals and divided regions in which the connection electrode is positioned, and FIG. 5b is a diagram showing the divided regions of one cycle of arrangement of the excitation electrodes in the first embodiment;

FIG. 6 is a block diagram showing an arrangement of a signal processing section;

FIG. 7 is a flowchart showing an algorism of processing to be performed by the signal processing section;

FIG. 8 is a diagram showing waveforms of the excitation signals to be applied to the excitation electrodes and detection signals generated by the excitation signals which are different from these in FIG. 4;

FIG. 9 is a diagram showing a second embodiment of the present invention in which three excitation-electrode sets are provided;

FIG. 10a is a table showing relation between combinations of detection signals and divided regions in which the connection electrode is positioned, and FIG. 10b is a diagram showing the divided regions of one cycle of arrangement of the excitation electrodes in the second embodiment;

FIG. 11 is a diagram showing a third embodiment of the present invention in which λ number is counted;

FIG. 12 is a flowchart showing an algorism of processing in the third embodiment; and

FIG. 13 a diagram showing arrangement of divided regions in the third embodiment.

### DETAILED DESCRIPTION

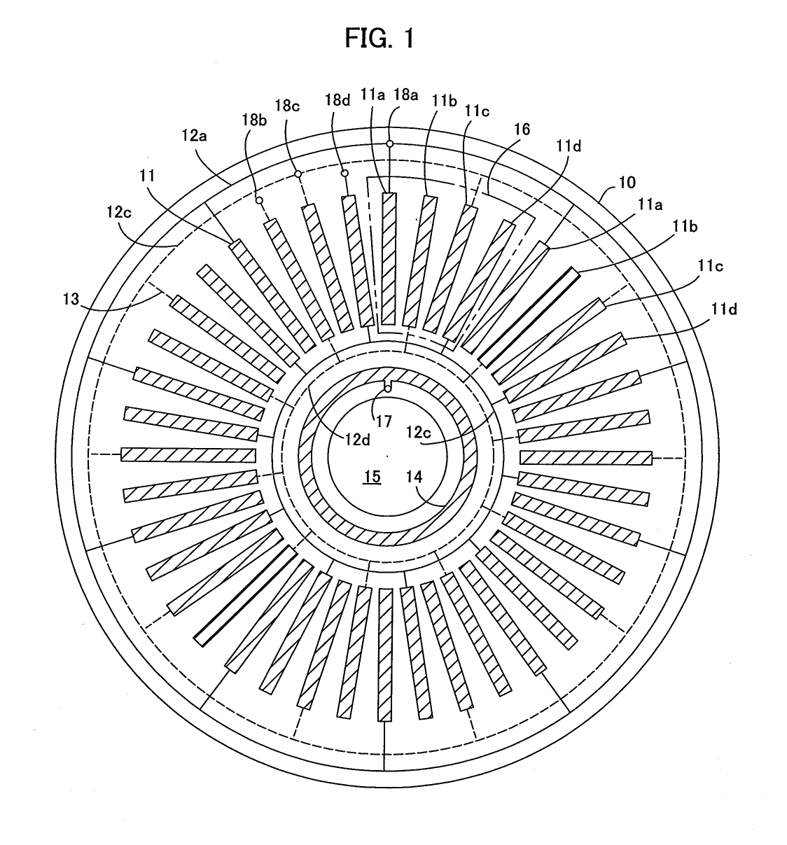

FIG. 1 shows a stator for use in a capacitance-type encoder according to the present invention. A stator 10 is a stationary disk-like plate having a through hole 15 at a center thereof and a plurality of excitation electrodes 11 arranged to extend in radial directions at constant intervals on one surface of the stator 10. The excitation electrodes 11 are arranged to form a plurality of excitation-electrode sets that are electrically independent from each other and each of the excitation-electrode sets consists of excitation electrodes arranged cyclically and electrically connected with each other, as described later.

The stator 10 is made of board material having an insulation surface and appropriate rigidity, such as glass-epoxy material, paper-Bakelite (trademark) laminated material, material obtained by applying molten ceramic to glass, ceramics such as alumina, metals such as iron and aluminum or semiconductor such as silicone, or by coating such material with isolation resin, or by isolating such material by air layer formed by isolation beads.

A conducting layer such as the excitation electrodes 11 on the stator 10 may be formed by photo-etching a conductive layer made of rolled cupper foil, evaporated chrome, etc. or by forming a conductive layer of conductive ink by inkjet, silk screen or offset printing.

Four successive excitation electrodes 11a, 11b, 11c and 11d form an excitation-electrode group 16 such that ten excitation-electrode groups in total are formed in this example. The excitation electrodes 11a, 11b, 11c or 11d in the same order in the different groups 16 are electrically connected with each other by conducting lines shown by solid lines or dotted lines in FIG. 1 to form four excitation-electrode sets 11A, 11B, 11C and 11D. The conducting lines shown by solid lines are arranged on a surface where the excitation electrodes 11 are provided, and the conducting lines shown by dotted lines are arranged on a surface opposite to the surface where the excitation electrodes 11 are provided.

As shown in FIG. 1, every fourth excitation electrodes 11a, 11b, 11c or 11d form four excitation-electrode sets 11A, 11B, 11C and 11D for four phases. The excitation electrodes in each set are electrically connected with each other via ring-shaped conductors 12a, 12b, 12c or 12d and supply conductors 13. The respective phases of the excitation electrodes are electrically excited by exciting means having four phases. In order to electrically connect every fourth excitation electrodes 11a, 11b, 11c or 11d in the respective excitation-electrode groups 16 such that the four excitation electrodes in each excitation-electrode group 16 are electrically independent from each other, the excitation electrodes, the ring-shaped conductors and the supply conductors are electrically connected by means of through-hole technique. The through-hole technique is generally known as a manufacturing technique of a printed board.

A ring-shaped receiving electrode 14 is provided to be electrically dependent from the excitation electrodes 11 at an inner portion of the stator 10 on the surface on which the excitation electrodes 11 are provided. The receiving electrode 14 is provided with a detection signal output terminal 17 for outputting detection signals received by the receiving electrode 14.

In FIG. 1, the receiving electrode 14 is arranged on the surface on which the excitation electrodes 11 are formed and at the portion inner than the excitation electrodes 11. However, the receiving electrode 14 may be provided on a surface opposite to the surface on which the excitation electrodes 11 are formed as long as the receiving electrode 14 receives detection signals by electrostatic induction with the sending electrode 22 on the movable element 20. In FIG. 1, the receiving electrode 14 is provided at the inner portion of the stator 10 so as to confront the sending electrode 22 of the movable element 20, however, the receiving electrode 14 may be provided at an outer portion of the stator 10 in a case where the sending electrode 22 is arranged at an outer portion of the movable element 20.

The through hole 15 formed at the center of the stator 10 is not an essential element of the capacitance-type encoder and may be omitted if it is not necessary for use.

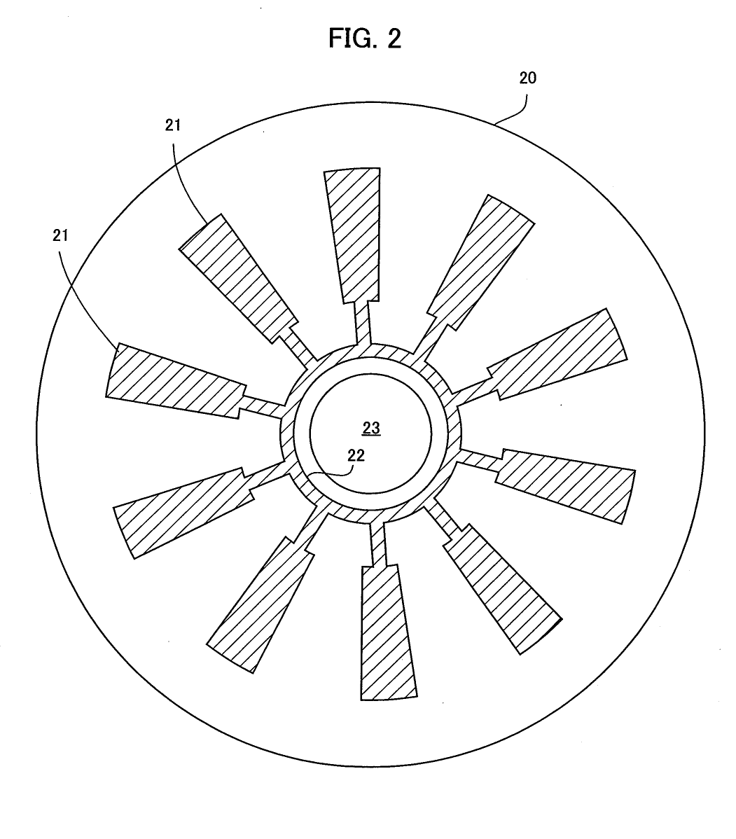

FIG. 2 shows a movable element 20 for use in the capacitance-type encoder. The movable element 20 is a disk-shaped rotor having a through hole 23. A plurality of connection electrodes 21 are formed on a surface of the movable element 20 to extend in radial directions. In the example shown in FIG. 2, ten connection electrodes 21 are provided. These connection electrodes 21 are electrically connected with a sending electrode 22 formed at a central portion of the movable element 20 so that a detection electrode of a single phase is constituted with the sending electrode 22.

The stator 10 and the movable element 20 are positioned such that the surface of the stator 10 on which the excitation electrodes 11 are formed confronts the surface of the movable element 20 on which the connection electrodes 21 are formed, so that the detection electrode constituted by the plurality of connection electrodes 21 detects excitation signals applied to the excitation electrodes 11 of the stator 10 according to the principle of electrostatic induction.

The signals generated in the detection electrode varies according to the relative position of the movable element 20 with respect to the stator 10 and the excitation signals applied to the excitation electrodes 11.

An alternating current signal of single phase detected by the detection electrode of the movable element 20 is sent to the receiving electrode 14 of the stator 10 by electrostatic induction between the sending electrode 22 on the movable element 20 and the receiving electrode 14 of the stator 10. Thus, the sending electrode 22 and the receiving electrode 14 are capable of transmitting the detection signals in a non-contact manner. A slip ring or a rotary transducer may be employed for transmitting the detection signals from the movable element 20 to the stator 10, other than the device utilizing the electrostatic induction.

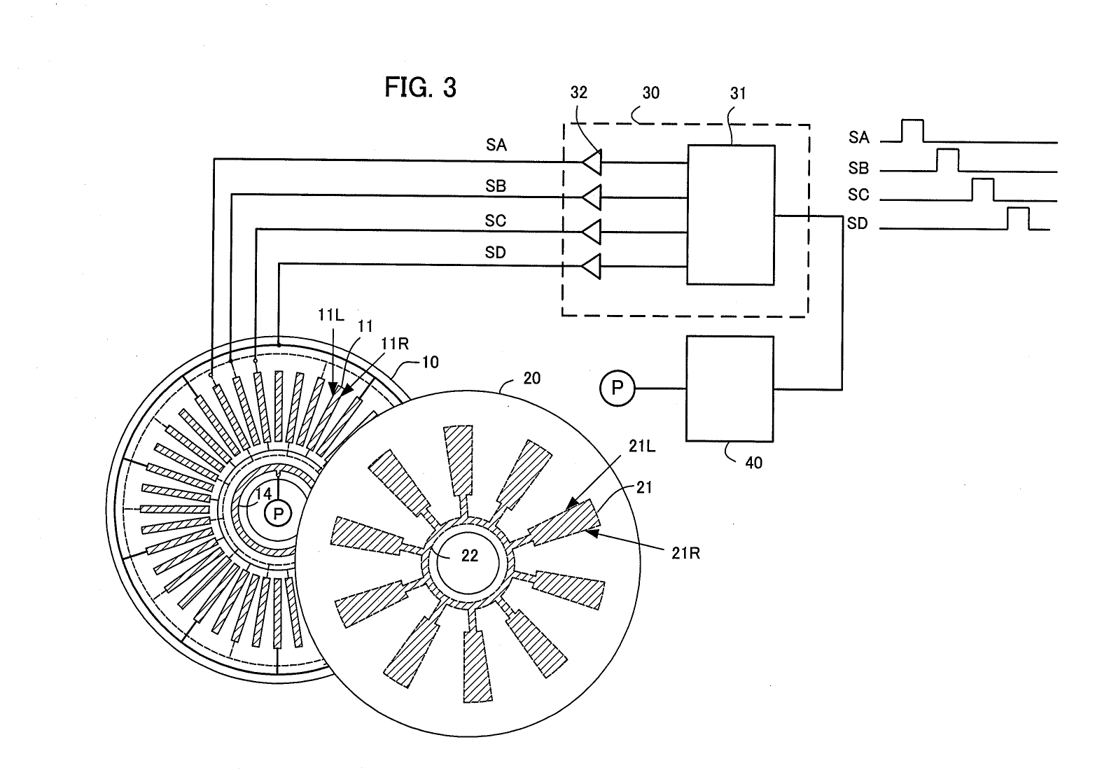

FIG. 3 schematically shows a capacitance-type encoder having the stator and the movable element according to a first embodiment of the present invention. The surface of the movable element 20 with the connection electrodes 21 provided thereon is arranged to confront the excitation electrodes 11 of the stator 10 with a predetermined gap in between and the movable element 20 is rotatably supported to be coaxial with the stator 10. The gap between the stator 10 and the movable element 20 is set generally to 150 μm to 200 μm in the case where an arranging pitch of the excitation electrodes is 200 μm, for example.

Outputs of the excitation means 30 are connected to the respective supply terminals 18a, 18b, 18c and 18d for the respective phases. The excitation means 30 comprises a sequencer 31 for successively outputting excitation signals SA, SB, SC and SD of single pulse voltages at predetermined intervals and a driver 32 for amplifying the signals outputted from the sequencer 31. The detection signal output terminal 17 of the stator 10 and the signal processing section 40 are electrically connected and the detection signals SG received by the receiving electrode 14 of the stator 10 are inputted to the signal processing section 40.

A way of detecting a rotational position (angle) of the movable element by the above capacitance-type encoder will be explained below.

As described, the stator 10 is provided with four excitation-electrode sets 11A, 11B, 11C and 11D arranged to be displaced clockwise, so that the four successive excitation electrodes 11a, 11b, 11c and 11d are arranged cyclically in this order. In one cycle of arrangement of the excitation electrodes 11a, 11b, 11c and 11d, the excitation electrode 11a indicates 0 degree, the excitation electrode 11b indicates 90 degree, the excitation electrode 11c indicates 180 degree and the excitation electrode 11d indicates 270 degree in respective excitation electrode groups.

As shown in FIG. 3, a left one of two sides 21L and 21R of each connection electrode 21 extending in radial directions of the movable element 20 is set to a reference line 21L of the rotational position of the movable element 20, and a left one of two sides 11L and 11R of one excitation electrode 11 extending in radial directions is set to a reference line 11L of the position of the stator 10.

One cycle of arrangement of the excitation electrodes 11a, 11b, 11c and 11d in each excitation-electrode group 16 is divided by the number of the excitation-electrode sets 11A, 11B, 11C and 11D, i.e. four in this example, so that divided regions for detection of position of the connection electrode 21 are determined using the reference line 11L of the stator 10. The capacitance-type encoder of the present embodiment determines in which divided region the reference line 21L of the connection electrode 21 is positioned, and output the determination results.

The sequencer 31 of the excitation means 30 applies positive pulse voltages which are independent from each other for the four phases of the excitation-electrode sets 11A, 11B, 11C and 11D and the detection signals SG generated in the connection electrodes 21 and received by the receiving electrode 14 are stored in the signal processing section 40, so that it is determined which one of the four divided regions the reference line 21L of the connection electrodes 21 is positioned in based on the combination pattern of the detected signals SG.

According to this embodiment, with the arrangement of the four sets and ten groups of excitation-electrodes 11, a rotational position of the movable element 20 can be determined with resolution of a fortieth part per one rotation of the movable element 20.

The detection signals SG include positive voltages and negative voltages responding to leading edges and trailing edges of the pulse voltages of the excitation signals. In this example, the signal processing section 40 operates to adopt positive voltages of the detection signals SG as effective signals and ignore the negative voltages.

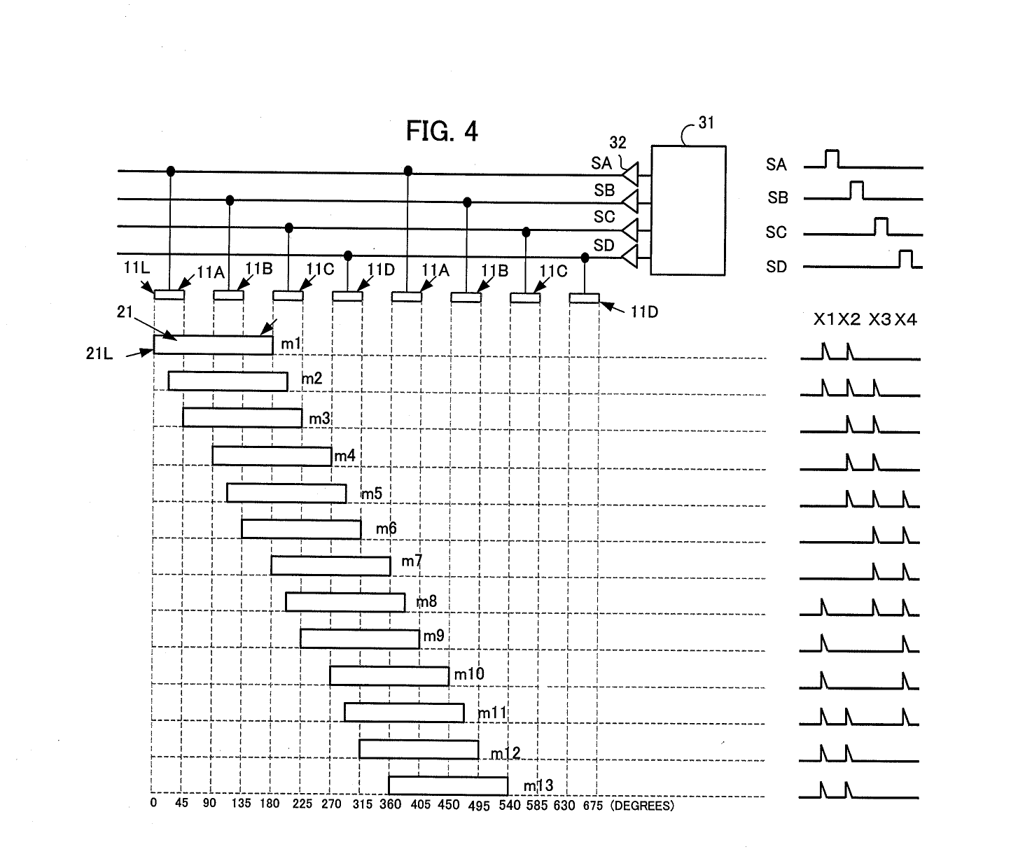

The position detection of the movable element will be explained in detail referring to FIG. 4.

FIG. 4 shows various positions of the connection electrode 21 of the movable element 20 with respect to the excitation electrodes 11 on the stator 10, and also the excitation signals selectively applied to the excitation electrodes 11 and detection signals generated at respective positions of the connection electrode 21.

In the example of FIG. 4, the sequencer 31 applies the same positive pulse in the order of excitation electrodes 11A→11B→11C→11D. Angles with respect to the cycle of arrangement of the excitation electrodes are indicated at the lower portion of FIG. 4. In the example of FIG. 4, the excitation-electrode set 11A indicates 0, 360, . . . degrees, the electrode set 11B indicates 90, 450, . . . degrees, the electrode set 11C indicates 180, 540, . . . degrees and the electrode set 11D indicates to 270, 630, . . . degrees.

In FIG. 4, a left side 11L of one excitation electrode in the excitation electrode set 11A is used as a reference of detection of a rotational position of the connection electrode 21. The connection electrode 21 depicted at the uppermost position indicates a case where the reference line 21L is positioned at 0 degree. In this position m1, since the connection electrode 21 confronts the excitation electrode set 11A and the excitation electrode set 11B, detection signals appear only when excitation signals are applied to the excitation electrode set 11A and the excitation electrode set 11B. The detection signals (voltages) indicated by X1, X2 appear in the receiving electrode 14 when the excitation signals are applied.

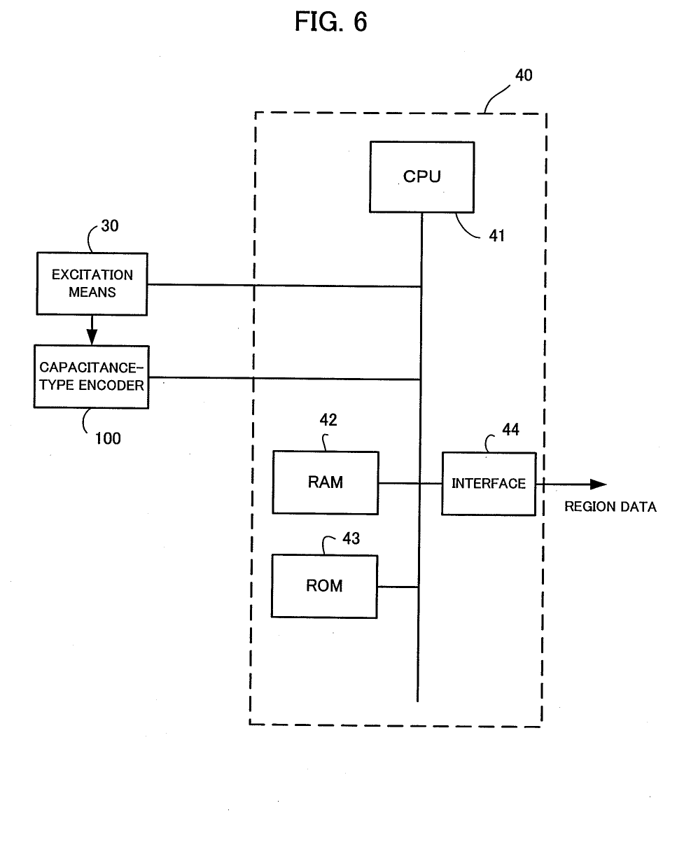

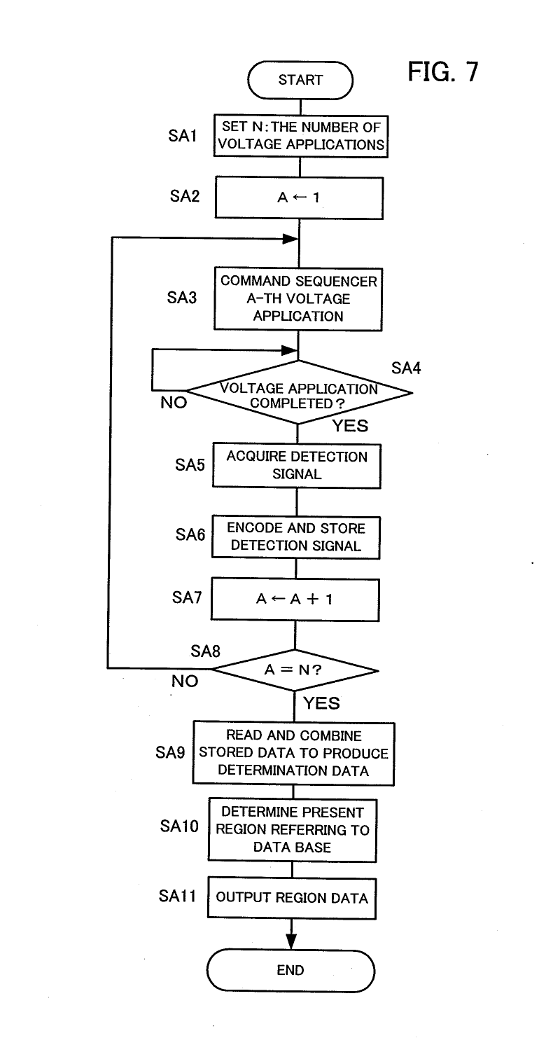

An embodiment of the signal processing section 40 will be explained referring to FIG. 6 and the processing to be performed by the signal processing section 40 will be explained referring to FIG. 7. The signal processing section 40 receives the detection signals SG from the capacitance-type encoder 100 and stores the received signals in the RAM 42. Then, the acquired data are combined and status data are read from the status data table in the ROM 43 based on the combined data. These arithmetic operations are performed by the CPU 41.

An algorithm of processing shown in FIG. 7 will be explained.

[Step SA1]: The number of voltage applications are set to a variable N.

[Step SA2]: “1” is set to a variable A.

[Step SA3]: A-th voltage application is commanded to the sequencer.

[Step SA4]: It is determined whether the voltage application is completed, and if not the determination is repeated. If the voltage application is completed, the procedure proceeds to Step SA5.

[Step SA5]: The detection signal is acquired from the receiving electrode.

[Step SA6]: The detection signal is encoded and stored. Each detection signal may take two statuses of a positive value and of a negative value or zero, and thus can be represented by one bit information.

[Step SA7]: “1” is added to the variable A.

[Step SA8]: It is determined whether the variable A equals the variable N. If the determination result is yes, the procedure proceeds to Step SA9. If the determination result is no, the procedure returns to Step SA3.

[Step SA9]: The stored data are read and combined to produce determination data.

[Step SA10]: It is determined in which divided region the connection electrode is positioned referring to the status data table storing the relation between the combination of the detection signals and the corresponding divided-region.

[Step SA11]: The determined divided-region data are outputted.

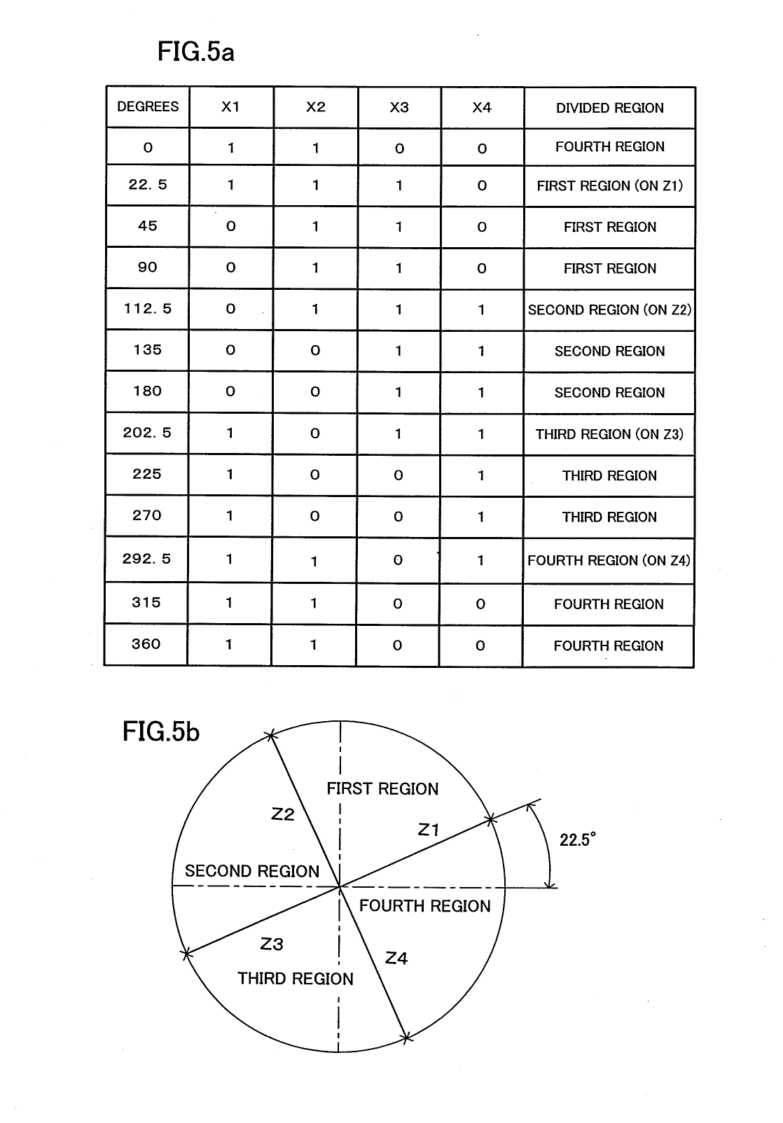

FIG. 5a shows a status data table storing relation between combinations of detection signals SG and divided regions in which the reference line of the connection electrode is positioned, as shown in FIG. 4. Referring to the status data table, it can be determined in which region the reference line 21 L of the connection electrode 21 is positioned based on the combination pattern of the detection signals SG. Lines Z1 to Z4 shown in FIG. 5b are boundaries of the divided regions and these lines are included in the first to fourth regions, respectively.

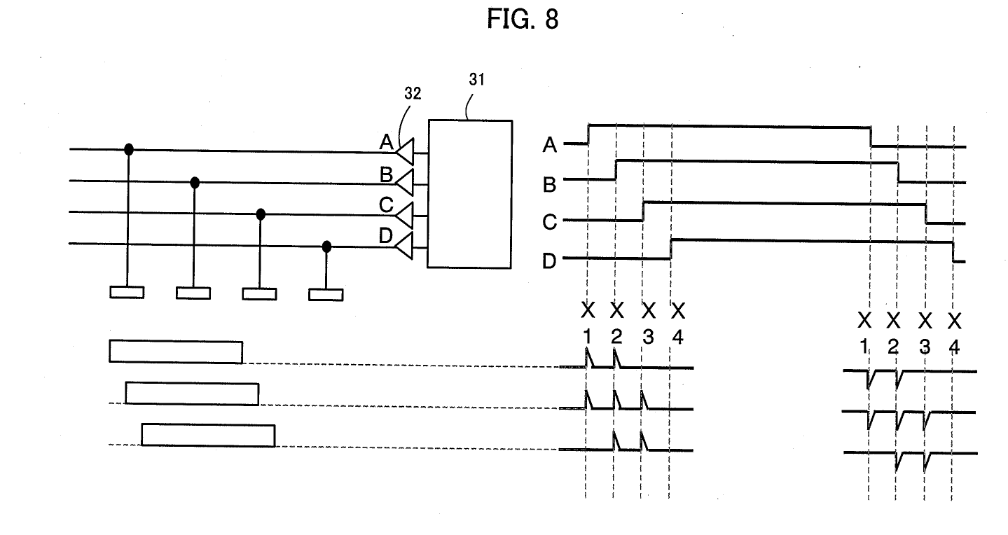

FIG. 8 shows excitation signals to be applied to the excitation electrodes that are different from the excitation signals shown in FIG. 4.

In the example of FIG. 4, the excitation pulses are outputted to the respective phases in the order of excitation electrodes 11A→11B→11C→11D in a manner that a subsequent pulse is outputted after one excitation pulse is returned to zero, however, in the example of FIG. 8, the respective pulses are overlapped.

In the example of FIG. 4, the signal processing section 40 adopts positive voltages of the detection signals SG to be effective, however, in this example, the signal processing section 40 adopts both of the positive and negative voltages of the detection signals SG to be effective.

In the example of FIG. 4, one determination result is obtained by one output of excitation signals, however, according to the way of applying the excitation signals as shown in FIG. 8, two determination results, i.e. a determination result based on the detection signals responding to leading edges of the pulses of the excitation signals, and a determination result based on the detection signals responding to trailing edges of the pulses of the excitation signals, can be obtained.

It should be noted that since the detection signal responding the leading edge and the detection signal responding the trailing edge of the excitation signal are inversed, it is necessary to perform processing of inversing signs of the detection signals responding the trailing edges of the excitation signals or modifying the contents of the stored data, etc.

A second embodiment in which three phases of the excitation electrodes are provided will be explained.

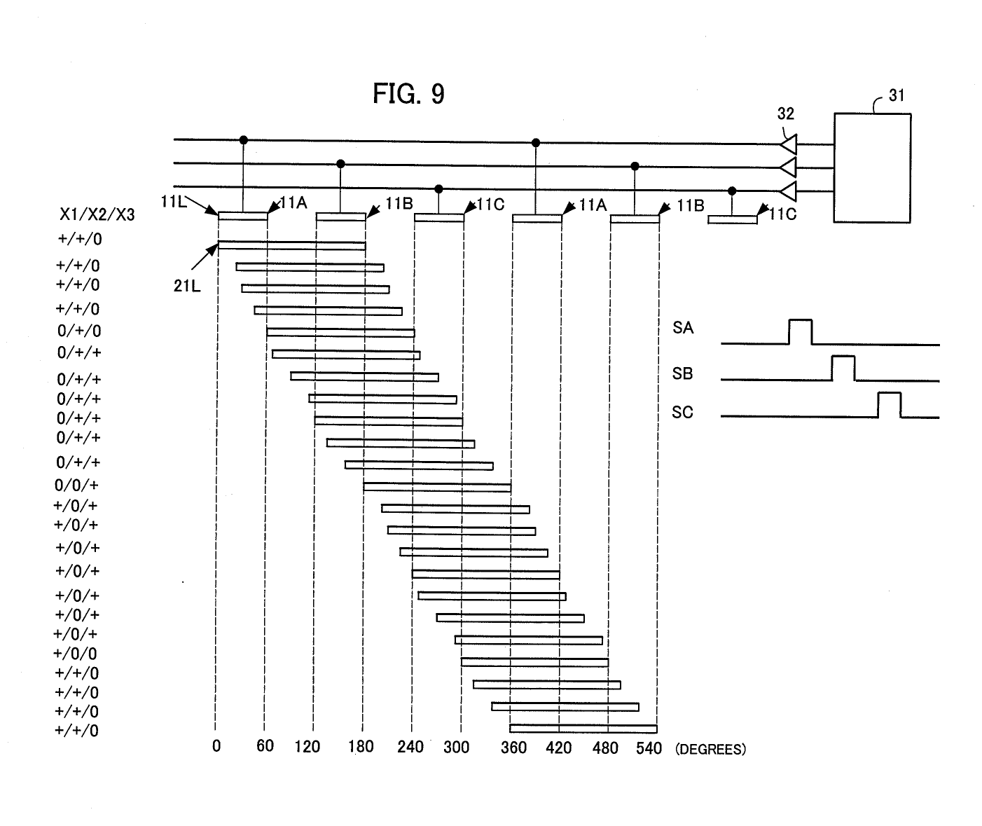

In this embodiment, as shown in FIG. 9, the stator includes three excitation-electrode sets 11A, 11B and 11C arranged clockwise in this order. Arrangement of respective excitation electrodes in the three excitation electrode sets 11A, 11B and 11C constitutes one cycle. The excitation electrode set 11A indicates 0, 360, . . . degrees, the excitation electrode sets 11B indicates 120, 480, . . . degrees and the excitation electrode set 11C indicates 240, 600, . . . degrees.

The capacitance-type encoder of this embodiment determines in which one of the three divided regions the reference line 21L of the connection electrode 21 of the movable element 20 is positioned with respect to the reference line 11L of the excitation electrode 11 and outputs the determination result.

For the detection, the sequencer 31 of the excitation means 30 applies pulse voltages independently for the three phases of the excitation electrode sets 11A, 11B and 11C and the detection signals SG generated in the receiving electrode 14 are stored in the signal processing section 40, so that it is determined in which one of the three divided regions the reference line 21L of the connection electrode 21 is positioned based on the combination of the detection signals SG.

The detection will be explained in detail referring to FIG. 9. FIG. 9 shows positions of the connection electrode 21 of the movable element 20 with respect to the excitation electrodes 11 on the stator 10, and also the excitation signals selectively applied to the excitation electrodes 11 from the sequencer 31 and the detection signals at the respective positions.

In the example of FIG. 9, the sequencer 31 applies the same pulse in the order of excitation electrodes 11A→11B→11C. Angles with respect to the cycle of arrangement of the excitation electrodes are shown at the lower portion of FIG. 9, and the excitation electrode set 11A indicates 0, 360, . . . degrees, the excitation electrode set 11B indicates 120, 480, . . . degrees, the excitation electrode set 11C indicates 240, 600, . . . degrees, as already mentioned.

In FIG. 9, a left side 11L of one excitation electrode of the excitation electrode set 11A is used as a reference of detection of a position of the connection electrode 21. The connection electrode 21 depicted at the uppermost position indicates a case where the reference line 21L is positioned at 0 degree. In this position, since the connection electrode 21 confronts the excitation electrode 11A and the excitation electrode 11B, detection signals (voltages) appear only when excitation signals are applied to the excitation electrode set 11A and the excitation electrode set 11B.

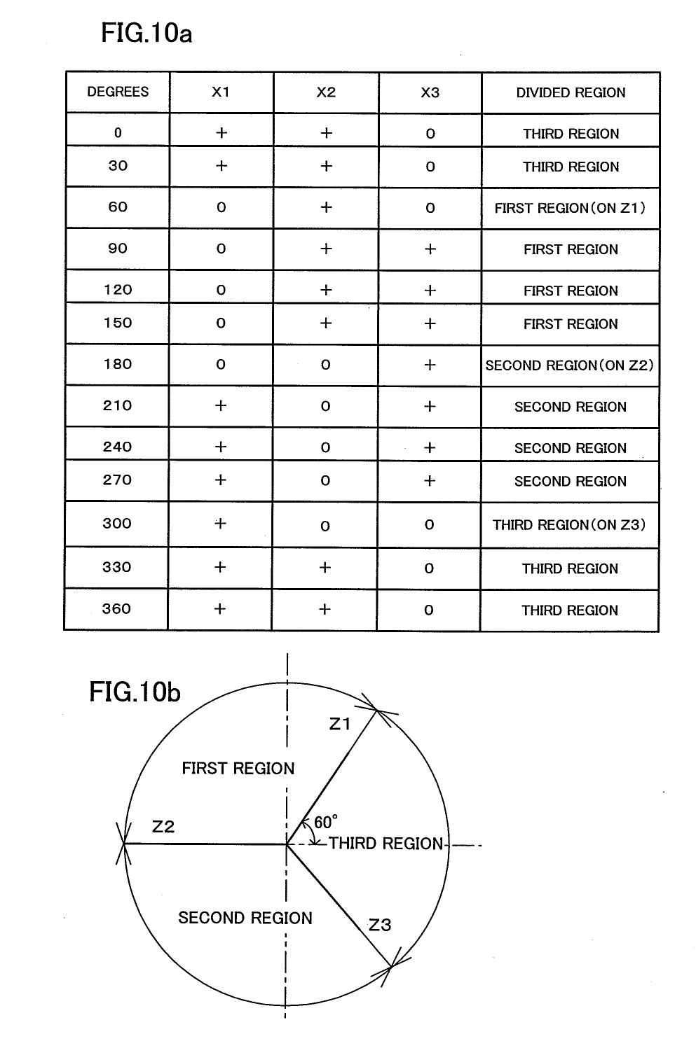

FIG. 10a shows a status data table storing relation between combinations of detection signals and divided regions in which the connection electrode is positioned as shown in FIG. 9. Referring to the status data table, it can be determined in which region the reference line of the connection electrode is positioned based on the combination of the detection signals. Lines Z1 to Z3 in FIG. 10b are boundaries of the divided regions and these lines are included in the first to third regions, respectively.

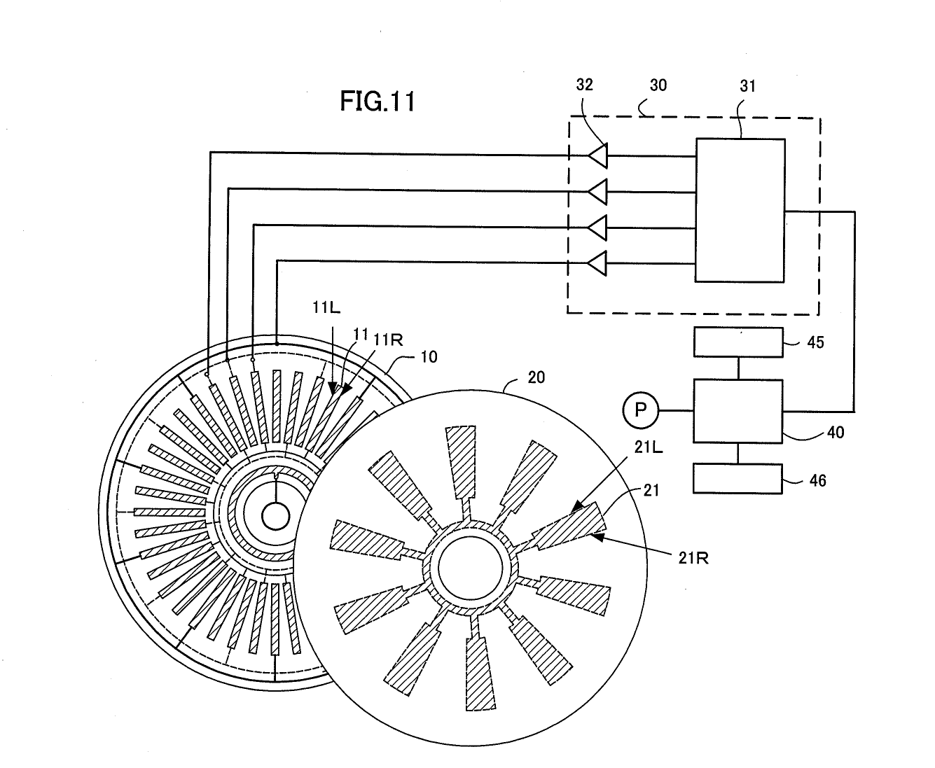

A third embodiment of the present invention will be described referring to FIGS. 11-13.

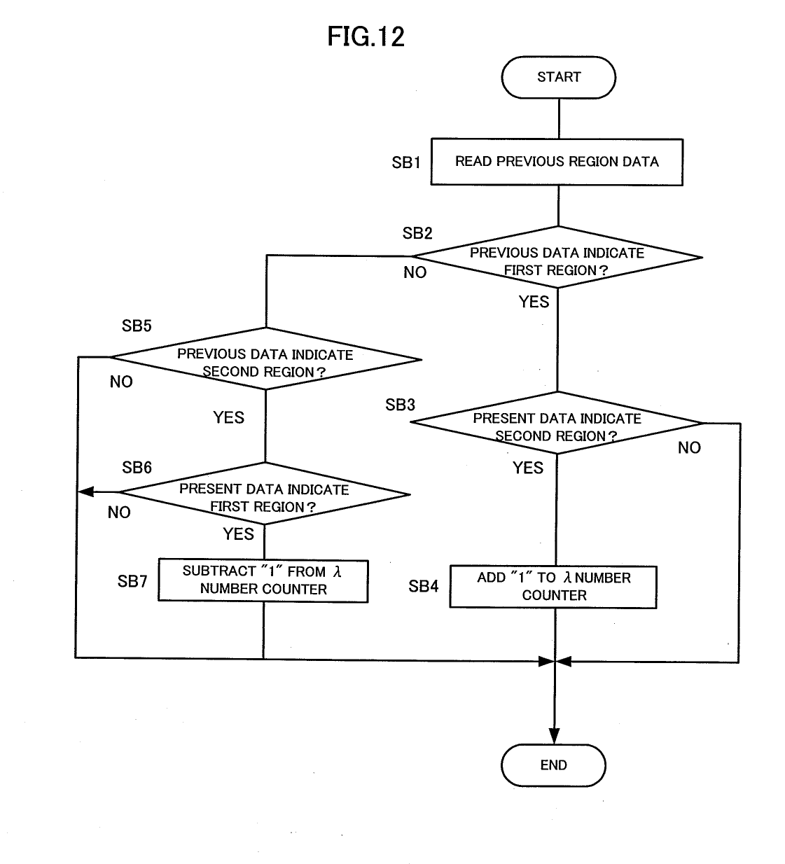

FIG. 11 shows a capacitance-type encoder having four-phase excitation electrodes 11 in which a signal processing section 40 has a region register 45 for storing the preceding divided region data, and a λ number counter 46 for storing the λ number which is updated each time when the movement of the movable element 20 exceeds one λ (one cycle of the arrangement of excitation electrodes). The way of counting the λ number using the region register 45 and the λ number counter 46 will be explained referring to FIG. 12.

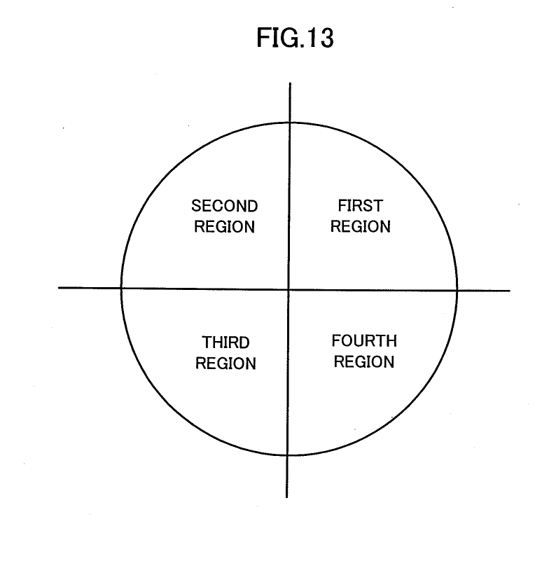

As shown in FIG. 13, a first divided region to a fourth divided region are predetermined in counterclockwise. In this example, a boundary between the first region and the second region is set to a changeover of λ number such it is determined that the movable element 20 has moved over 1λ when the reference line 21L of the connection electrode 21 enters the second region from the first region. The motion from the first region to the second region clockwise is within one λ so that the λ number counter is not updated. A first step of the determination is to determine whether the value of the region register indicates the first region or the second region. As a second step, it is determined whether the region data obtained in the present processing period indicates the first region or the second region.

Respective steps of the flowchart shown in FIG. 12 will be explained.

[Step SB1]: The previous region data are read.

[Step SB2]: It is determined whether the previous region data indicate the first region or not. If the previous region data are determined to indicate the first region the procedure proceeds Step SB3, and if not the procedure proceeds Step SB5.

[Step SB3]: It is determined whether the present region data indicate the second region. If the present region data are determined to indicate the second region the procedure proceeds Step SB4, and if not the procedure is terminated.

[Step SB4]: The λ number counter is increased by “1” and stored.

[Step SB5]: It is determined whether the previous region data indicate the second region. If the previous region data are determined to indicate the second region the procedure proceeds Step SB6, and if not the procedure is terminated.

[Step SB6]: It is determined whether the present region data indicate the first region. If the present region data are determined to indicate the first region the procedure proceeds Step SB7, and if not the procedure is terminated.

[Step SB7]: The λ number counter is decreased by “1” and stored, and the procedure is terminated.

With this embodiment, a rotational position of the movable element 20 over a plurality of cycles of the arrangement of the excitation electrodes 11 can be detected securely.

What is claimed is:

1. A capacitance-type encoder comprising:
a stator having at least three excitation-electrode sets electrically independent from each other, each set being constituted of excitation electrodes arranged cyclically and electrically connected with each other so that a predetermined number of excitation-electrode groups are formed, and a receiving electrode electrically independent from the excitation electrodes;
a movable element provided movably relative to said stator and having connection electrodes arranged to confront the excitation electrodes of said stator cyclically to have the same number as the excitation-electrode groups, and a sending electrode electrically connected with the connecting electrodes and arranged to confront the receiving electrode of said stator;
excitation means for applying excitation signals of binary voltages to the excitation-electrode sets of said stator periodically in a predetermined sequence; and
signal processing means for processing detection signals generated in the connection electrodes of said movable element and received by the receiving electrode through the sending electrode when the excitation signals are applied to the excitation electrodes of said stator to determine which one of divided regions said movable element is positioned in based on a combination pattern of the detection signals, said divided regions being predetermined by dividing one cycle of arrangement of excitation electrodes in each excitation-electrode group by the number of the excitation-electrode sets.

2. A capacitance-type position encoder according to claim 1, wherein said excitation signals comprise positive or negative pulse voltages.
